(19) United States
(12) Patent Application Publication
(10) Pub. No.: US 2011/0158582 A1
(43) Pub. Date: Jun. 30, 2011

(54) STRUCTURE OF A SEMICONDUCTOR DEVICE HAVING A WAVEGUIDE AND METHOD OF FORMING THE SAME

(76) Inventors: Tzung-I Su, Yun-Lin County (TW); Ming-I Wang, Taipei County (TW); Bang-Chiang Lan, Taipei City (TW); Te-Kan Liao, Hsinchu City (TW); Chao-An Su, Kaohsiung County (TW); Chien-Hsin Huang, Taichung City (TW); Hui-Min Wu, Hsinchu County (TW); Tzung-Han Tan, Taipei City (TW); Min Chen, Taipei County (TW); Meng-Jia Lin, Changhua County (TW)

(21) Appl. No.: 12/649,337

(22) Filed: Dec. 30, 2009

(51) Int. Cl. G02B 6/122; G02B 6/136; H01L 21/70

(52) U.S. Cl. 385/14; 438/31; 257/E21.532

(57) ABSTRACT

A method of forming the structure of the semiconductor device having a waveguide. Firstly, a SOI substrate including a bulk silicon, an insulating layer, and a silicon layer is provided and a device region and a waveguide region are defined on the SOI substrate. Afterwards, a protection layer and a patterned shielding layer are formed to cover the waveguide region and expose the device region. Subsequently, a recess is formed by etching the protection layer, the silicon layer and the insulating layer and thereby the bulk silicon is exposed. After that, an epitaxial silicon layer is formed in the recess and a semiconductor device is subsequently formed on the epitaxial silicon layer. Also, the present invention conquers the poor electrical performance of the semiconductor device integrated into the SOI substrate.

### BACKGROUND OF THE INVENTION

1. Field of the Invention

The present invention relates to a structure of a semiconductor device having a waveguide and a method of forming the same, and more particular to a structure of a semiconductor device having a waveguide and the method of forming the same by virtue of integrating the silicon on insulator (SOI) substrate for fabrication.

2. Description of the Prior Art

With the rapid increase in demand for high-end integrated circuit products, the manufacturing of CMOS SOI integrated circuits allows the fabrication of scaled down transistors with faster operation due to the preferred characteristics such as low capacitance, low leakage and low operation voltage, such that the SOI CMOS process have become a mainstream in next generation.

However, the traditional semiconductor process utilizes metal connection lines serving the role responsible for the signal connection between the semiconductor device and the peripheral component, whereas the signal transmission speed arrives to its limitation depending on the conventional metal connection line. Also, since the scaled down semiconductor device process is reaching a limitation, the electronic transmission speed is not easy to continue increasing. In brief, it is therefore that the over-mature technology both in the semiconductor device and the metal connection lines leads to the limitation of the whole signal transmission speed. Also, it should be noted that the semiconductor device has disadvantages such as poor heat dissipation and electro-magnetic interference (EMI) in operation.

In recent years, because the photons having no electric charges and mass are compared with electrons, the problems such as cross talk and electric magnetic interruption (EMI) may be ignored. Also, the potential application of the photons in the signal transmission has been gradually emphasized and developed. Especially, it is therefore an important research focus to utilize the CMOS process for integrating the fabrication of the waveguide responsible for the light signal transmission, such that the signal transmission speed may be promoted obviously. Accordingly, the silicon fabrication process integrating all of the silicon waveguide and related silicon photonic devices becomes a primary development trend. Precisely speaking, when the transmission theoretical basis of the silicon waveguide is that when the reflection material with low refractive index encases the silicon transmission layer, the lights moving on the silicon transmission layer will be reflected between the surface of the reflection materials to produce a light-driven effect. Consequently, the optical interconnect may replace the electrical interconnect.

The conventional SOI CMOS process integrating the fabrication of into the SOI substrate has disadvantages. For instance, additional expenditure may be used and an additional effort for the preferred model parameters of the semiconductor device which have to be tuned and established should be put. Accordingly, it is an important subject to improve the disadvantages due to the conventional CMOS SOI process integrating the fabrication of the semiconductor device and the waveguide.

### SUMMARY OF THE INVENTION

One object of the present invention is to provide a structure of a semiconductor device having a waveguide and a method of forming the same to improve the aforementioned problems.

In order to achieve the above-mentioned object, the present invention proposes a method of forming a structure of a semiconductor device having a waveguide. The method includes at least the following steps. Firstly, a SOI substrate is provided. Subsequently, a device region and a waveguide region are defined on the SOI substrate. Afterwards, the SOI substrate includes a bulk silicon, an insulating layer covering the bulk silicon and a silicon layer covering the insulating layer. After that, a protection layer is formed on the SOI substrate. Then, a patterned mask layer is formed on the SOI substrate to cover the waveguide region and expose the device region. Afterwards, an etching step is utilized to etch the protection layer, the silicon layer and the insulating layer to form a recess and expose the bulk silicon. After that, an epitaxial process is performed to form an epitaxial silicon layer in the recess. Finally, a semiconductor device is formed on the epitaxial silicon layer.

In order to achieve the above-mentioned object, the present invention proposes a structure of a semiconductor device having a waveguide. The structure of the semiconductor device includes a SOI substrate, a waveguide, an epitaxial silicon layer and a semiconductor device. A device region and a waveguide region are defined on the SOI substrate. The SOI substrate includes a bulk silicon, a patterned insulating layer disposed on the bulk silicon and a waveguide channel layer disposed on the patterned insulating layer. A recess is disposed between the bulk silicon, the patterned insulating layer and the waveguide channel layer. A waveguide is disposed in the waveguide region. An epitaxial silicon layer is disposed on a surface of the bulk silicon in the recess. A semiconductor device is disposed on the epitaxial silicon layer.

The structure of the semiconductor device having a waveguide and the method of forming the same of the present invention have the following advantages. Firstly, the present invention utilizes a SOI substrate having an epitaxial silicon layer and the SOI CMOS process together for the fabrication of the waveguide to satisfy the preferred process compatibility. In addition, mass production for the structures of the semiconductor device having a waveguide may be achievable. Also, the present invention conquers the poor electrical performance of the semiconductor device integrated into the SOI substrate. Consequently, the structure of the semiconductor device having a waveguide and the method of forming the same of the present invention successfully integrates the waveguide fabrication to achieve an optical interconnection effect, such that the signal transmission speed is significantly improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 8 are schematic diagrams illustrating the method of forming the semiconductor device having a waveguide of the present invention.

### DETAILED DESCRIPTION

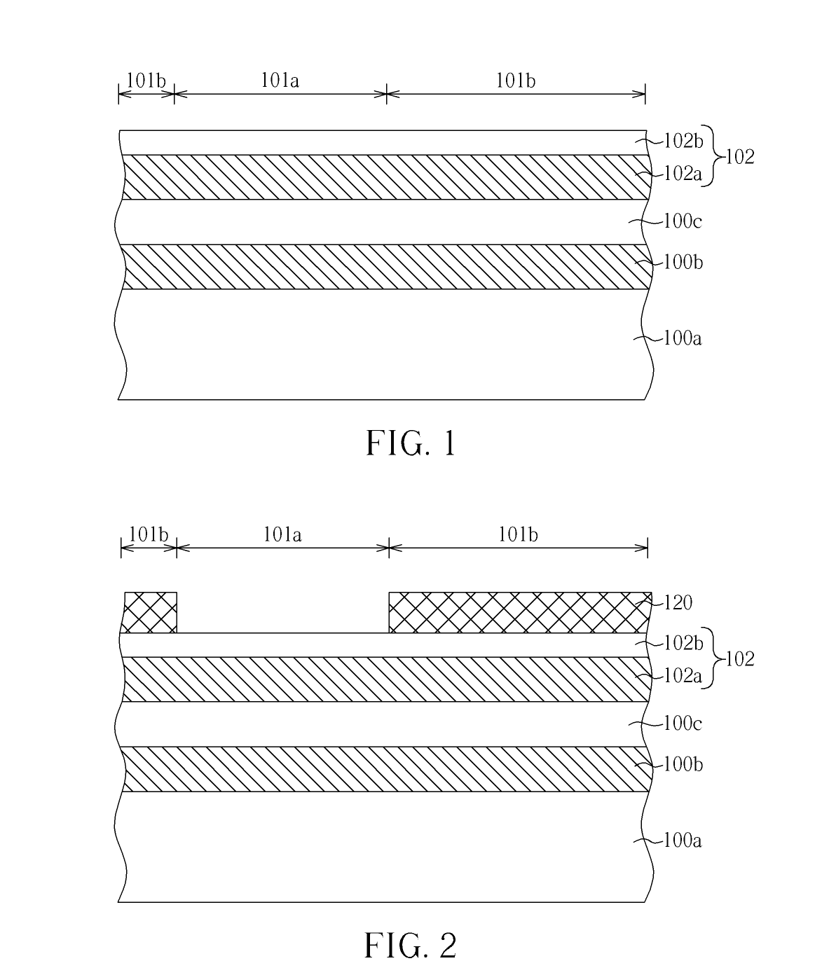

With reference to FIG. 1 to FIG. 8, FIG. 1 to FIG. 8 are schematic diagrams illustrating the method of forming the semiconductor device having a waveguide of the present invention. As illustrated in FIG. 1, firstly, a SOI substrate 100 is provided, and the SOI substrate 100 includes a bulk silicon 100a, an insulating layer 100b covering the bulk silicon 100a, a silicon layer 100c made of single crystal silicon and covering the insulating layer 100b, and a device region 101a and a waveguide region 101b are defined on the SOI substrate. Subsequently, a protection layer 102 is formed on the SOI substrate 100, wherein the protection layer 102 may be single material layer or composite structure layer. In this embodiment, the protection layer 102 may include two structure layers, whereas the steps of forming the protection layer 102 includes performing a first deposition process firstly to form a silicon oxide layer 102a and subsequently performing a second deposition process to form a nitrided layer 102b on the silicon oxide layer 102a. Precisely speaking, the aforementioned first and second deposition methods may include atmospheric pressure chemical vapor deposition (APCVD), low-pressure chemical vapor deposition (LPCVD) or ultrahigh vacuum chemical vapor deposition (UHVCVD), but are not limited to this.

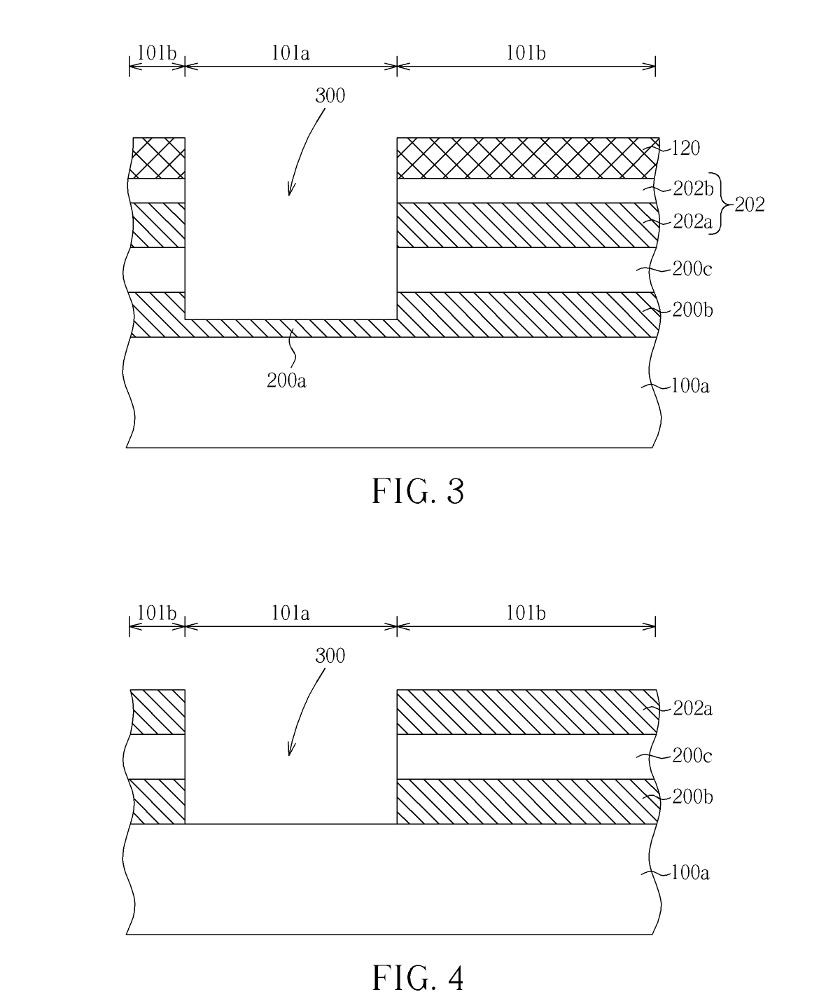

As illustrated in FIG. 2, afterwards, the method of forming the semiconductor device having a waveguide of the present invention firstly forms a patterned mask layer 120 such as patterned photoresist layer on the surface of the protection layer 102 disposed on the top of the SOI substrate 100 to cover the waveguide region 101b for exposing the device region 101a. As illustrated in FIG. 3, subsequently, the patterned mask layer 120 is served as an etching mask to perform an etching step for forming the recess 300 in the device region 101a. In this embodiment, the etching step includes a dry etching process in the first stage and a wet etching process in the second stage. In the first stage, the dry etching process is utilized to sequentially etch the protection layer 102, the silicon layer 100c and the insulating layer 100b to a destined depth so as to form a patterned protection layer 202, a patterned silicon layer 200c, a patterned insulating layer 200c and a shielding layer 200a, wherein the patterned protection layer 202 includes a patterned silicon oxide layer 202a and a patterned nitrided layer 202b, and the shielding layer 200a is a remaining insulating layer 100b.

Precisely speaking, in this embodiment, the shielding layer 200a is formed by virtue of utilizing the dry etching process for etching the insulating layer 100b to the destined depth. It is therefore that the insulating layer 100b is not completely etched out by the dry etching process. The purpose of disposing the shielding layer 200a is to prevent the bottom of the bulk silicon 100a from suffering physical etching damage during the dry etching process.

As illustrated in FIG. 4, after removing the patterned mask layer 120, in the second stage, a wet etching process or a plurality of wet etching processes is utilized to remove the shielding layer 200a and the patterned nitrided layer 202b to form a recess 300. The wet etchant for removing the shielding layer 200 is, for example, a buffer oxide etchant (BOE). The wet etchant for removing the patterned nitrided layer 202b is, for example, hot phosphoric acid. When a plurality of wet etching processes is used to remove the shielding layer 200a and the patterned nitrided layer 202b, the patterned nitrided layer 202b is preferably removed firstly and the shielding layer 200a is then removed.

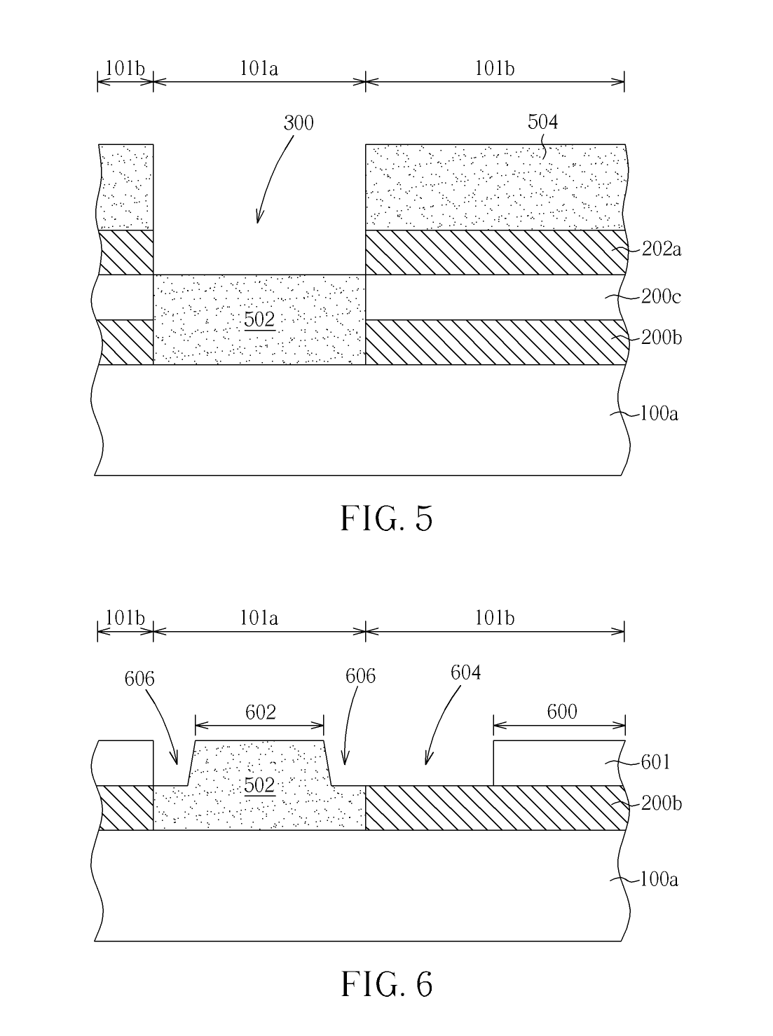

After that, as illustrated in FIG. 5, an epitaxial process is performed to respectively form an epitaxial silicon layer 502 in the recess 300 and a patterned poly-silicon layer 504 on the patterned silicon oxide layer 202a due to the different material property of the recess 300 and the patterned silicon oxide layer 202a. Also, the epitaxial process of the present invention may be performed to selectively form a portion of epitaxial silicon in the recess 300 by virtue of selective epitaxial growth (SEG), but is not limited to this. In addition, the epitaxial process in this embodiment is preferable to form an epitaxial silicon layer 502 with a growth thickness to the height of the top of the silicon layer 200c.

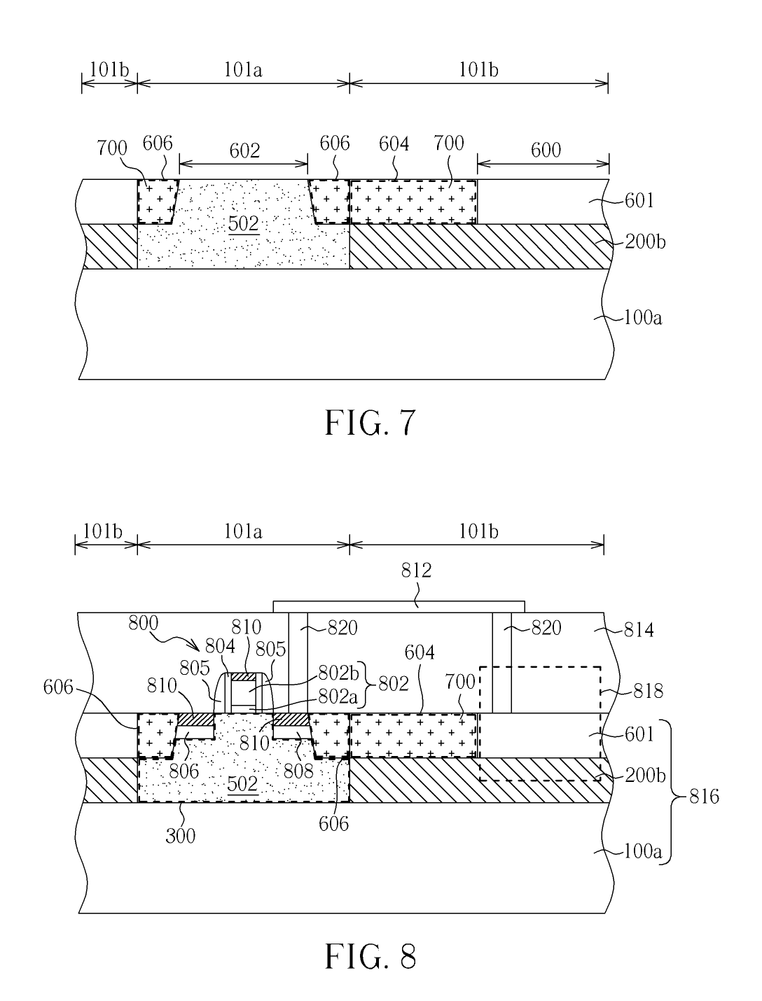

As illustrated in FIG. 6, subsequently, an etching process or a chemical mechanical polishing (CMP) process is utilized to remove the poly-silicon layer 504 and the patterned silicon oxide layer 202a. Afterwards, a mask having a shallow trench isolation pattern and a waveguide pattern is utilized for a standard shallow trench isolation (STI) process. For instance, a patterned mask layer is formed at first. By using the patterned mask layer, a portion of the patterned silicon oxide layer 202a and a portion of the epitaxial silicon layer 502 are etched to form at least a rib waveguide channel layer 601, a buried recess 604 and an active trench region 606. Subsequently, as illustrated in FIG. 7, a dielectric material is filled in the buried recess 604 and the active region trench 606 and subsequently planarized to form a buried insulating layer 700, such that a waveguide channel layer region 600 and an active region 602 are defined on the SOI substrate 100. Also, the forming buried insulating layer 700 may electrically disconnect the waveguide channel layer 601 in the waveguide region 101b and the semiconductor device in the device region 101a. In this embodiment, the buried insulating layer 700 and the patterned insulating layer 200b are substantially made of the same material such as silicone compound, but are not limited to this.

As illustrated in FIG. 8, after that, a standard semiconductor process is performed to form a semiconductor device 800 on the epitaxial silicon layer 502 in the active region 602. In this embodiment, it should be noted that the semiconductor device 500 may include metal oxide semiconductor (MOS), bipolar junction transistor (BJT), thin film transistor (TFT) and complementary metal oxide semiconductor (CMOS) devices, but is not limited to this. Also, the semiconductor device 500 may be any device which may serve as a control switch or have other functions. For example, taking the MOS transistor as a semiconductor device 500 for illustration, the step of forming the MOS transistor includes at least the following steps. Firstly, a gate electrode 802a and a gate dielectric layer 802b are formed and stacked on the epitaxial silicon layer 502 to form a gate structure 802. After that, at least a spacer 804 made of silicon oxide layer or nitrided layer is formed on periphery of the gate structure 802. Then, anion implantation process is performed to form lightly-doped source region and drain region in the epitaxial silicon layer 502 on the peripheral of the gate structure 802. Afterwards, an offset spacer 805 is formed on the periphery of the spacer 804. Subsequently, another ion implantation process is performed to form a source region 806 and a drain region 808 in the epitaxial silicon layer 502 on the peripheral of the gate structure 802. After that, a rapid thermal annealing (RTA) process is performed to activate the dopants in the source region 806 and the drain region 808 at a high temperature between 900° C. and 1050° C., such that the damage on the epitaxial silicon layer 502 during the ion implantation process may be repaired. Finally, a metal layer is deposited on the gate electrode 802a, the source region 806 and the drain region 808. In addition, a rapid thermal annealing process is performed to make the contact portions respectively between the metal layer and the gate electrode 802a, between the metal layer and the source region 806 and between the metal layer and the source region 808 form silicide layers 810. It should be noted that the aforementioned MOS transistor of the semiconductor device 800 of the present invention is a preferred embodiment, whereas the semiconductor device 800 may be adjusted and modified as required. The spirit of this invention is not limited to the details of the process for forming the semiconductor device. It is therefore that the goal of the present invention is to focus on the integrated fabrication of the waveguide 818 and the semiconductor device 800 on SOI substrate.

At last, an interlayer insulating layer 814 is formed to cover the semiconductor device 800, the waveguide channel layer 601 and the buried insulating layer 700. Subsequently, at least a connection line 812 is formed on the interlayer insulating layer 814 and thereby electrical connects the semiconductor device 800 and the waveguide channel layer 601 via the contact plug 820. In this embodiment, the connection line 812 may be pulled to the silicide layer 810, such that the semiconductor device 800 may control the voltage applied on the waveguide channel layer 601. It is therefore that the semiconductor device 800 electrically connects the waveguide channel layer 601 of the waveguide 618 through the connection line 812. In this embodiment, as illustrated in FIG. 8, a waveguide 818 is the combination of the patterned insulating layer 200b, the waveguide channel layer 601 and the interlayer insulating layer 814. In the spatial arrangement, the waveguide channel layer 601 is disposed between the interlayer insulating layer 814 and the patterned insulating layer 200b, and the interlayer insulating layer 814 and the patterned insulating layer 200b are reflection layers encasing the waveguide channel layer 601. Also, the reflective index of the patterned insulating layer 200b is smaller than the reflective index of the interlayer insulating layer 814 and is smaller than the reflective index of the waveguide channel layer 601, such that the lights moving on the waveguide channel layer 601 will be reflected between the surface of the reflection materials to produce a light-driven effect.

In this embodiment, it should be noted that since the waveguide is designed to be operated in specific wavelengths. In order to accord with the conventional optical communication system, the wavelengths of near-infrared lights such as 1.55 micrometer are commonly used. However, in this embodiment, the preferred wavelengths of the infrared lights are between 800 nanometers and 1800 nanometers, but are not limited to this. On the other hand, as for the materials, the patterned insulating layer 200b, the buried insulating layer 700 and the interlayer insulating layer 814 may include silicon oxide, aluminum oxide, aluminum nitride and any materials having dielectric characteristic. It is therefore that the reflective indexes of the patterned insulating layer 200b and the buried insulating layer 700 have distinguishing difference with that of the waveguide channel layer.

On the other hand, since FIG. 8 is an ultimate schematic diagram illustrating the method of forming the structure of the semiconductor device having a waveguide, FIG. 8 is also a schematic diagram illustrating the structure of the semiconductor device having a waveguide. With reference to FIG. 8, the structure of the semiconductor device 800 having a waveguide 818 of the present invention includes a SOI substrate 816, a waveguide 818, an epitaxial silicon layer 502 and a semiconductor device 800. A device region 101a and a waveguide region 101b are defined on the SOI substrate 816, and the SOI substrate 816 includes a bulk silicon 100a, a patterned insulating layer 200b disposed on the bulk silicon 100a, and a waveguide channel layer 601 disposed on the patterned insulating layer 200b. Finally, an interlayer insulating layer 814 covering and disposed on the top of the waveguide channel layer 601, a waveguide 818 and a semiconductor device 800. In this embodiment, in the device region 101a, a recess 300 disposed between the bulk silicon 100a, the patterned insulating layer 200b and the patterned silicon layer 200c and thereby the recess 300 provides a reserved space for disposing the epitaxial silicon layer 502. After that, the semiconductor device 800 is disposed on the epitaxial silicon layer 502. Also, a buried insulating layer 700 is disposed on a portion of the surface of the patterned insulating layer 200 and on the epitaxial silicon layer 502, and the buried insulating layer 700 is responsible for electrically disconnecting the device region 101a and the waveguide region 101b. Finally, an interlayer insulating layer 814 covers and is disposed on the top of the waveguide channel layer 601 and a semiconductor device. At least a connection line 812 disposed on the top of the interlayer insulating layer 814 electrically connects the semiconductor device 800 and the waveguide channel layer 601 via the contact plug 820. In addition, in the waveguide region 101b, the waveguide 818 is disposed in the waveguide region 101b, wherein the waveguide 818 is substantially a combination of the patterned insulating layer 200b, a portion of the insulating layer 814 and the waveguide channel layer 601. In this embodiment, the semiconductor device 500 may include metal oxide semiconductor (MOS), bipolar junction transistor (BJT), thin film transistor (TFT) and complementary metal oxide semiconductor (CMOS) devices. Also, the semiconductor device 500 is preferable as a metal oxide semiconductor (MOS). However, the forming of the metal oxide semiconductor (MOS) is described in the aforementioned paragraphs and no redundant description is provided here. As for the materials for the structure of the semiconductor device having a waveguide, the waveguide channel layer 601 is a single crystal layer. The buried insulating layer 700 and the patterned insulating layer 200b are substantially made of the same material including silicon oxide. In this embodiment, the selected materials should satisfy that the reflective index of the patterned insulating layer 200b is smaller than the reflective index of the waveguide channel layer 601, and the reflective index of the interlayer insulating layer 814 is smaller than the reflective index of the waveguide channel layer 601.

In summary, the structure of the semiconductor device having a waveguide and the method of forming the same of the present invention have the following advantages. Firstly, the present invention utilizes a SOI substrate having an epitaxial silicon layer disposed on the bulk silicon and the standard SOI CMOS process together for the fabrication of the waveguide to satisfy the preferred process compatibility, such that mass production for the structures of the semiconductor device having a waveguide may be achievable. Also, the mature metal oxide semiconductor process may be utilized to adjust the parameters and electrical performance of the MOS device disposed on the bulk silicon. Secondly, the structure of the semiconductor device having a waveguide and the method of forming the same of the present invention conquers the poor electrical performance of the semiconductor device integrated into the SOI substrate. Thirdly, the waveguide channel layer of the SOI substrate of the present invention utilizes single crystal silicon material layer to minimize the optical loss. Fourthly, the structure of the semiconductor device having a waveguide and the method of forming the same of the present invention successfully integrates the waveguide fabrication to achieve an optical interconnection effect, such that the signal transmission speed is significantly improved. Also, the clock delay phenomena generated due to the use of metal connection lines may be conquered, and the development for new low dielectric material may be omitted.

Those skilled in the art will readily observe that numerous modifications and alterations of the device and method may be made while retaining the teachings of the invention.

What is claimed is:

1. A method of forming a structure of a semiconductor device having a waveguide, the method comprising:
providing a SOI substrate, the SOI substrate having a device region and a waveguide region defined thereon, the SOI substrate comprising a bulk silicon, an insulating layer covering the bulk silicon, and a silicon layer covering the insulating layer;
forming a protection layer on the SOI substrate;
forming a patterned mask layer on the SOI substrate to cover the waveguide region and expose the device region;
utilizing an etching step to etch the protection layer, the silicon layer and the insulating layer to form a recess and expose the bulk silicon;
performing an epitaxial process to form an epitaxial silicon layer in the recess; and
forming a semiconductor device on the epitaxial silicon layer.

2. The method of claim 1, wherein the etching step comprises utilizing a dry etching process to etch the protection layer, the silicon layer and the insulating layer to form a patterned protection layer, a patterned silicon layer, a patterned insulating layer and a shielding layer.

3. The method of claim 2, wherein the etching step comprises utilizing a wet etching process to remove the shielding layer after the dry etching process to remove the shielding layer for forming a recess between the patterned protection layer, the patterned silicon layer, the patterned insulating layer and the bulk silicon.

4. The method of claim 1, further comprising utilizing a shallow trench isolation (STI) process after the epitaxial process.

5. The method of claim 4, wherein the shallow trench isolation process comprises an etching step to etch a portion of the patterned silicon oxide layer to form a waveguide channel layer.

6. The method of claim 5, further comprising forming an interlayer insulating layer covering the semiconductor device and the waveguide channel layer.

7. The method of claim 6, further comprising a step of removing the protection layer completely before forming the interlayer insulating layer.

8. The method of claim 1, wherein the protection layer comprises a silicon oxide layer and a nitrided layer.

9. The method of claim 1, wherein the semiconductor device comprises metal oxide semiconductor (MOS) transistor, bipolar junction transistor (BJT), thin film transistor (TFT) or complementary metal oxide semiconductor transistor (CMOS) devices.

10. The method of claim 1, wherein a reflective index of the insulating layer is smaller than a reflective index of the silicon layer.

11. A structure of a semiconductor device having a waveguide, comprising:
a SOI substrate, the SOI substrate having a device region and a waveguide region defined thereon, the SOI substrate comprising a bulk silicon, a patterned insulating layer disposed on the bulk silicon and a waveguide channel layer disposed on the patterned insulating layer, and a recess disposed between the bulk silicon disposed in the device region, the patterned insulating layer and the waveguide channel layer;
a waveguide disposed in the waveguide region;
an epitaxial silicon layer disposed on a surface of the bulk silicon in the recess; and
a semiconductor device disposed on the epitaxial silicon layer.

12. The structure of the semiconductor device of claim 11, wherein the waveguide channel layer comprises a single crystal silicon layer.

13. The structure of the semiconductor device of claim 11, further comprising an interlayer insulating layer covering the semiconductor device and the waveguide channel layer.

14. The structure of the semiconductor device of claim 11, wherein the semiconductor device comprises metal oxide semiconductor (MOS), bipolar junction transistor (BJT), thin film transistor (TFT) or complementary metal oxide semiconductor (CMOS) transistor devices.

15. The structure of the semiconductor device of claim 11, wherein a reflective index of the patterned insulating layer is smaller than a reflective index of the waveguide channel layer.

16. The structure of the semiconductor device claim 13, wherein a reflective index of the interlayer insulating layer is smaller than a reflective index of the waveguide channel layer.
